(19) United States
(12) Patent Application Publication
(10) Pub. No.: US 2006/0054088 A1
(43) Pub. Date: Mar. 16, 2006

(54) Vapor phase epitaxial growth apparatus and semiconductor wafer production method

(75) Inventors: Yoshihiro Jagawa, Tokyo (JP); Naoki Ono, Tokyo (JP)

Correspondence Address: GREENBLUM & BERNSTEIN, P.L.C., 1950 ROLAND CLARKE PLACE, RESTON, VA, 20191, US

(73) Assignee: SUMCO Corporation, Tokyo (JP)

(21) Appl. No.: 11/224,054

(22) Filed: Sep. 13, 2005

(30) Foreign Application Priority Data
Sep. 14, 2004 (JP) 2004-266619

(51) Int. Cl. C23C 16/00

(52) U.S. Cl. 118/715; 118/663; 438/5

(57) ABSTRACT

A vapor phase epitaxial growth apparatus, comprising a chamber, to which a wafer is fed; a gas introduction device for introducing a reaction gas into the chamber; a gas flow amount sensor for detecting a flow amount of the reaction gas introduced by the gas introduction device; heaters for heating the wafer fed into the chamber; a heat adjusting device for adjusting heating energy by the heaters; a temperature sensors for detecting a temperature of the wafer fed into the chamber; a control device for receiving as parameters a gas flow amount detected by the gas flow amount sensor and a wafer temperature detected by the temperature sensors, obtaining an optimal value of heating energy for attaining the most uniform epitaxial film based on a predetermined simulation-model, and outputting the same to the heat adjusting device.

### BACKGROUND OF THE INVETION

1. Field of the Invention

The present invention relates to a vapor phase epitaxial growth apparatus for growing an epitaxial film on a surface of a wafer used for a semiconductor device and a production method of the semiconductor wafer.

2. Description of the Related Art

A single wafer vapor-phase growth apparatus has been widely used as a vapor-phase epitaxial growth apparatus for growing an epitaxial film having a high film quality on a wafer surface.

The single wafer vapor-phase growth apparatus has a passage-shaped chamber made by quartz and grows an epitaxial film on a wafer surface by placing a wafer on a disk-shaped susceptor obtained by coating silicon carbide on a graphite base material provided in the chamber and bringing the wafer react with a variety of material gases passing through the chamber while heating the wafer by a heater arranged on an outer surface of the chamber. As a material gas for vapor phase growing reaction, a chlorosilane based gas added with a dopant material gas of diborane (P-type), phosphine or arsine (N-type), and an epitaxial film is formed by thermal CVD reaction on the wafer surface.

In a vapor phase epitaxial growth step as such, it is significant to grow an epitaxial film having preferable crystalline to have a uniform film thickness, so that the growing condition, such as radiant heat transfer from the heater to the wafer and a flow of the reaction gas, has to be managed.

In the related art, there was an attempt of growing an epitaxial film by obtaining a relationship of irradiated heat transfer from the heater, a reaction gas flow and a film thickness distribution by a computer simulation method and setting an ideal condition to the growth apparatus, however, an actual temperature of the wafer changed sensitively due to deterioration of the heater over time and change of a flow amount of the reaction gas, so that it was difficult to secure a uniform film thickness as simulated.

### SUMMARY OF THE INVENTION

An object of the present invention is to provide a vapor phase epitaxial growth apparatus for obtaining an epitaxial film having a uniform film thickness and a production method of a semiconductor wafer.

To attain the above object, according to a first aspect of the present invention, there is provided a vapor phase epitaxial growth apparatus, comprising:
a chamber, to which a wafer is fed;
a gas introduction device for introducing a reaction gas to the chamber;
a gas flow amount detector for detecting a flow amount of the reaction gas introduced by the gas introduction device; a heater for heating the wafer fed into the chamber;
a heat adjusting device for adjusting heating energy by the heater;
a temperature detector for detecting a temperature of the wafer fed into the chamber;
a controller for receiving as parameters a gas flow amount detected by the gas flow amount detector and a wafer temperature detected by the temperature detector, obtaining an optimal value of heating energy for attaining the most uniform epitaxial film based on a predetermined simulation model, and outputting the same to the heat adjusting device.

Also according to a second aspect of the present invention, there is provided a production method of a semiconductor wafer for heating a wafer fed into a chamber and introducing a reaction gas into the chamber to form an epitaxial film on a surface of said wafer by thermal decomposition of said reaction gas, comprising the steps of:
detecting a flow amount of the reaction gas introduced into said chamber;
detecting a temperature of the wafer fed into said chamber;
inputting as parameters the gas flow amount detected by the above step and the wafer temperature detected by the above step, and obtaining an optimal value of heating energy for attaining the most uniform epitaxial film based on a predetermined simulation model; and
heating said wafer by the optimal value of heating energy obtained in the above step.

In the present invention, when a wafer fed in the chamber is heated and a reaction gas is introduced into the chamber to form an epitaxial film on the wafer surface by thermal decomposition of the reaction gas, an actual flow amount of the reaction gas introduced into the chamber and an actual temperature of the wafer fed to the chamber are detected and input as parameters to a modeling simulation program, and desired heating energy for attaining the most uniform epitaxial film is calculated by simulation. Then, an optimal value of the heating energy obtained by the simulation calculation is fed back to a vapor phase growth step, and the wafer is heated based on the optimal value.

Since all condition was input as parameters in the computer simulation method of the related art, it took a long time to obtain a desired estimated value (condition). While in the present invention, a flow amount of the reaction gas and a temperature of the wafer, which are significant factors in growing a uniform epitaxial film, are actually measured and input to the simulation program, so that desired heating energy can be obtained in a short time and feedback control in real-time can be attained.

Also, the computer simulation method of the related art was unable to predict deterioration of the heater over time and change of a flow amount of the reaction gas, so that an accurate expected value could not be obtained, while in the present invention, a reaction gas flow amount and wafer temperature are actually measured and assigned to the simulation program, so that it is possible to respond to deterioration of the heater over time if any, and an epitaxial film can be grown based on an accurate expected value.

To attain the above object, according to a third aspect of the present invention, there is provided a vapor phase epitaxial growth apparatus, comprising:
a chamber, to which a wafer is fed;
a gas introduction device for introducing a reaction gas to the chamber;
a gas flow amount adjusting device for adjusting a flow amount of the reaction gas by the gas introduction device;
a heater for heating the wafer fed into the chamber;
a heating energy detector for detecting heating energy supplied by the heater;
a temperature detector for detecting a temperature of the wafer fed into the chamber;
a controller for receiving as parameters heating energy detected by the heating energy detector and a wafer temperature detected by the temperature detector, obtaining an optimal value of a reaction gas flow amount for attaining the most uniform epitaxial film based on a predetermined simulation model, and outputting the same to the gas flow amount adjusting device.

Also, according to a fourth aspect of the present invention, there is provided a production method of a semiconductor wafer for heating a wafer fed into a chamber and introducing a reaction gas into the chamber to form an epitaxial film on a surface of said wafer by thermal decomposition of said reaction gas, comprising the steps of:
detecting heating energy supplied to the wafer fed into said chamber;
detecting a temperature of the wafer fed into said chamber;
inputting as parameters the heating energy-detected in the above step and the wafer temperature detected in the above step, and obtaining an optimal value of a reaction gas flow amount for attaining the most uniform epitaxial film based on a predetermined simulation model; and
introducing the reaction gas into said chamber by the optimal value of the reaction gas flow amount obtained in the above step.

In the present invention, when a wafer fed in the chamber is heated and a reaction gas is introduced into the chamber to form an epitaxial film on the wafer surface by thermal decomposition of the reaction gas, actual heating energy supplied to the wafer fed to the chamber and an actual temperature of the wafer are detected and input as parameters to the modeling simulation program, and a desired flow amount of the reaction gas for attaining the most uniform epitaxial film is calculated by a modeling simulation. Then, an optimal value of the flow amount of the reaction gas obtained by the simulation calculation is fed back to the vapor phase growth step, and the reaction gas is introduced into the chamber based on the optimal value.

Since all condition was input as parameters in the computer simulation method of the related art, it took a long time to obtain a desired estimated value (condition). While in the present invention, a temperature of the wafer, which becomes a significant factor in growing a uniform epitaxial film, is actually measured and input to the simulation program, so that a desired flow amount of the reaction gas can be obtained in a short time and feedback control in real-time can be attained.

Also, the computer simulation method of the related art was unable to predict deterioration of the heater over time and change of a flow amount of the reaction gas, so that an accurate expected value could not be obtained, while in the present invention, a wafer temperature is actually measured and assigned to the simulation program, so that it is possible to respond to deterioration of the heater-over time if any, and an epitaxial film can be grown based on an accurate expected value.

The present disclosure relates to subject matter contained in Japanese Patent Application No. 2004-266619, filed on Sep. 14, 2004, the disclosure of which is expressly incorporated herein by reference in its entirety.

### BRIEF DESCRIPTION OF DRAWINGS

These and other objects and features of the present invention will become clearer from the following description of the preferred embodiments given with reference to the attached drawings, in which:

FIG. 1 is a block diagram of a vapor phase epitaxial growth apparatus according to an embodiment of the present invention;

FIG. 2 is a view for explaining calculations in a control means in FIG. 1;

FIG. 3 is a flowchart of a control procedure in the control means in FIG. 1;

FIG. 4 is a block diagram of a vapor phase epitaxial growth apparatus according to another embodiment of the present invention;

FIG. 5 is a plan view of a chamber of the vapor phase epitaxial growth apparatus in FIG. 4; and

FIG. 6 is a flowchart of a control procedure in a control means in FIG. 4.

### DESCRIPTION OF THE PREFERRED EMBODIMENT

Below, embodiments of the present invention will be explained based on the drawings.

### First Embodiment

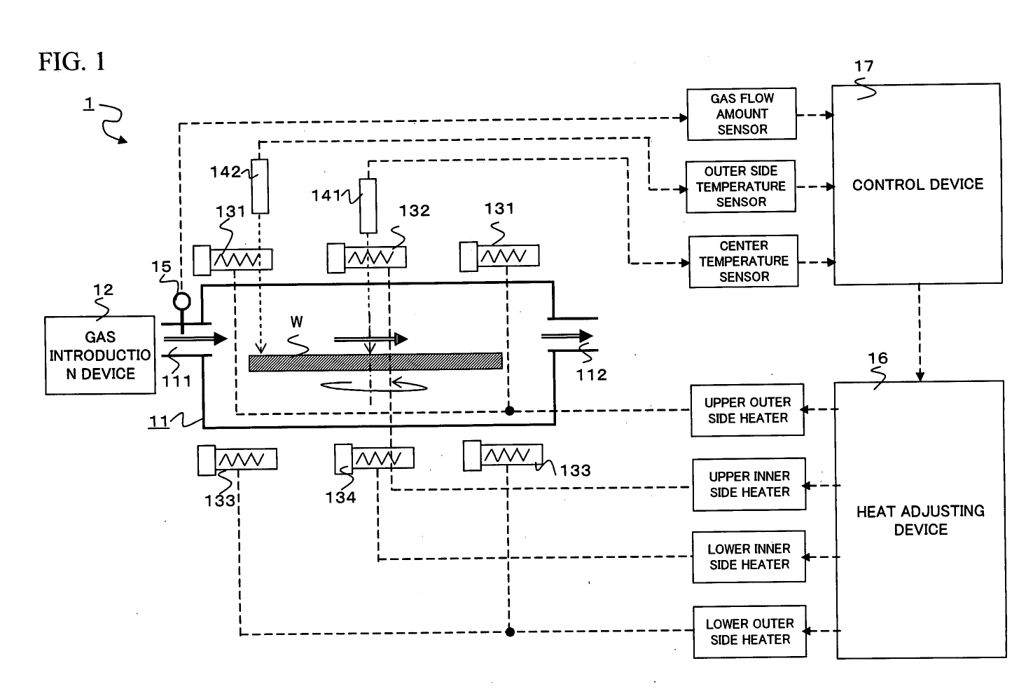

The present embodiment is a single wafer vapor phase epitaxial growth apparatus 1 (hereinafter, also simply referred to as a vapor phase growth apparatus 1) and provided with a chamber 11 composed of an upper dome and a lower done 4 attached to a dome mounting body, while the detailed configuration is omitted in FIG. 1. The upper dome and the lower dome composing the chamber 11 are made by quartz or other translucent material, and a wafer W fed in the chamber 11 is heated by a plurality of heaters composed of a halogen lamp as a heating source arranged at upper and lower parts of the chamber 11.

The heaters include upper outer side heaters 131 arranged at the outer side of an upper part, an upper inner side heater 132 arranged at the inner side of the upper part, lower outer side heaters 133 arranged at the outer side of a lower part and a lower inner side heater 134 arranged at the inner side of the lower part, and they are collectively called as heaters 13.

Power supplied to the respective heaters 13 is supplied from a heat adjusting device 16 and the heaters 131 to 134 are controlled separately. Heating energy of the heaters 131 to 134 is adjusted by the heat adjusting device 16 in accordance with an instruction from a control device 17.

A side surface of the chamber 11 is provided with a gas inlet 111, and a facing side surface thereto of the chamber 11 is provided with a gas outlet 112. A reaction gas-obtained by diluting a Si source, such as SiHCl₃, with a hydrogen gas and mixing therein a trace of dopant is introduced into the chamber 11 from the gas inlet 111 via the gas introduction device 12, and the introduced reaction gas passes through a surface of the wafer W to grow an epitaxial film, then, discharged from the gas outlet 112 to outside the vapor phase growth apparatus 1. A double-lined arrow in FIG. 1 indicates the reaction gas flow.

Note that the gas inlet 111 and the gas outlet 112 may be respectively divided into two gas inlets and two gas outlets, each of the upper and lower parts, so that the reaction gas can be introduced and discharged by using an upper gas inlet and an upper gas outlet while a carrier gas, such as a hydrogen gas, can be introduced to a lower side of the wafer W and discharged by using a lower gas inlet and a lower gas outlet. Consequently, dopant released from a back surface of the wafer W can be more effectively discharged to the outside of the vapor phase growth apparatus 1. Alternately, when introducing a carrier gas, such as a hydrogen gas, into the chamber 11 by dividing the gas inlet 111 to an upper part and a lower part, the reaction gas and the carrier gas for discharging the back surface dopant may be discharged from one gas outlet 112. Note that the specific configuration of the gas inlet 111 and the gas outlet 112 does not matter in the present invention and may be modified in accordance with need.

While not illustrated in FIG. 1, the wafer W fed into the chamber 11 is loaded on a support plate called a susceptor. The susceptor rotates at a predetermined speed by being driven by a rotation axis rotating about a center point of the wafer W (refer to an arrow). A material of the susceptor is not particularly limited and, for example, what obtained by coating a SiC film on a surface of a carbon base material is preferably used. Note that a method of conveying the wafer W to and from the susceptor is not particularly limited and either of a type of conveying the wafer by elevating and lowering a conveyor jig by using a Verneuil chuck and a type of supporting the lower surface of the wafer by a pin and conveying by elevating and lowering the pin may be applied.

The gas introduction device 12 comprises a pump for pneumatically transferring a reaction gas and carrier gas, and a gas pipe for guiding the gas and a flow amount adjusting valve for adjusting a flow amount of the gas, and a gas flow amount value in accordance with a growth condition is set to the flow amount adjusting valve.

Particularly, in the vapor phase growth apparatus 1 in the present embodiment, the gas inlet 111 for introducing the reaction gas is provided with a gas flow amount sensor 15 composed of an air flow meter, etc. to detect a flow amount of the reaction gas contributing to grow an epitaxial film of the wafer W and sends the flow amount to the control device 17. Note that the gas flow amount detection means according to the present invention is not limited to the gas flow amount sensor 15 of the present embodiment and it may detect an opening degree of the flow amount adjusting valve explained above.

Also, the vapor phase growth apparatus 1 of the present embodiment is provided with a center temperature sensor 141 composed of a radiation thermometer for detecting a temperature of the center (near the center) of the wafer W surface and an outer side temperature-sensor 142 composed of a radiation thermometer in the same way for detecting a temperature around the wafer W. As explained above, since the wafer W rotates at a constant speed due to rotation of the susceptor, the outer side temperature sensor 142 measures a temperature around the wafer W at certain time intervals to evenly obtain temperatures-around the wafer W. Then, actual temperatures of the wafer surface detected by the center temperature sensor 141 and the outer side temperature sensor 142 are sent to the control device 17.

The control device 17 sends an instruction to the heat adjusting device 16 as explained above to control power to be supplied to the heaters 131 to 134 and retrieves an actual flow amount Q of the reaction gas from the gas flow amount sensor 15 explained above at certain time intervals. Also, the control device 17 retrieves an actual temperature T1 of the center of the wafer W surface from the center temperature sensor 141 at certain time intervals and an actual temperature T2 around the wafer W surface from the outer side temperature sensor 142 at certain time intervals.

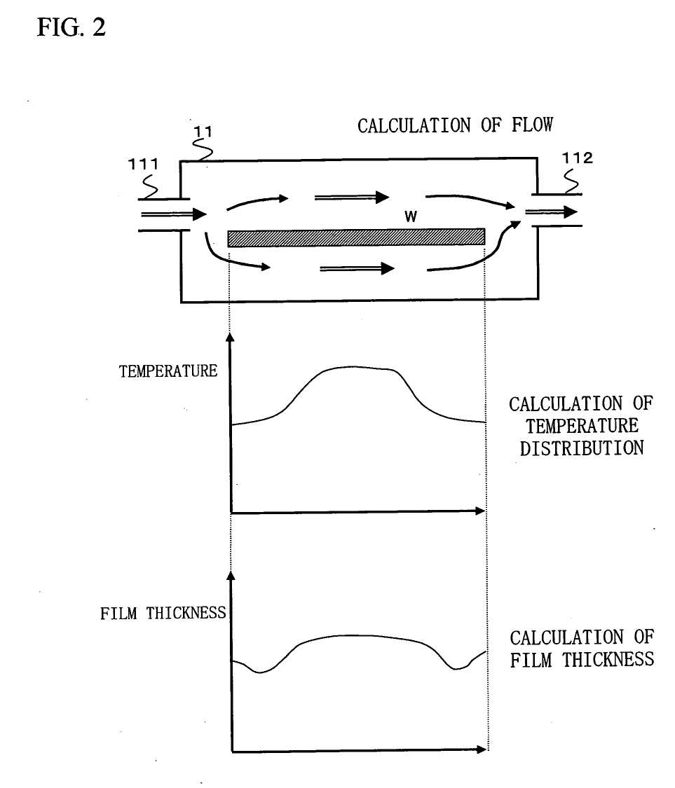

Then, the control device 17 calculates an actual temperature distribution as shown in FIG. 2 from the obtained surface temperatures T1 and T2 of the wafer and calculates a film thickness distribution from the obtained reaction gas flow amount Q. Here, when the obtained film thickness distribution is not in a range of satisfying desired film thickness-uniformity, power to be supplied to the heaters 131 to 134 and the distribution ratio (balance between the heaters) are calculated based on a simulation model, and optimal values of the power of the heaters 131 to 134 for attaining the most uniform film thickness are obtained. Then, the obtained optimal power values are sent to the heat adjusting device 16 and optimal power is supplied from the heat adjusting device 16 to the heaters 131 to 134.

Next, an operation of the vapor phase growth apparatus of the present embodiment will be explained.

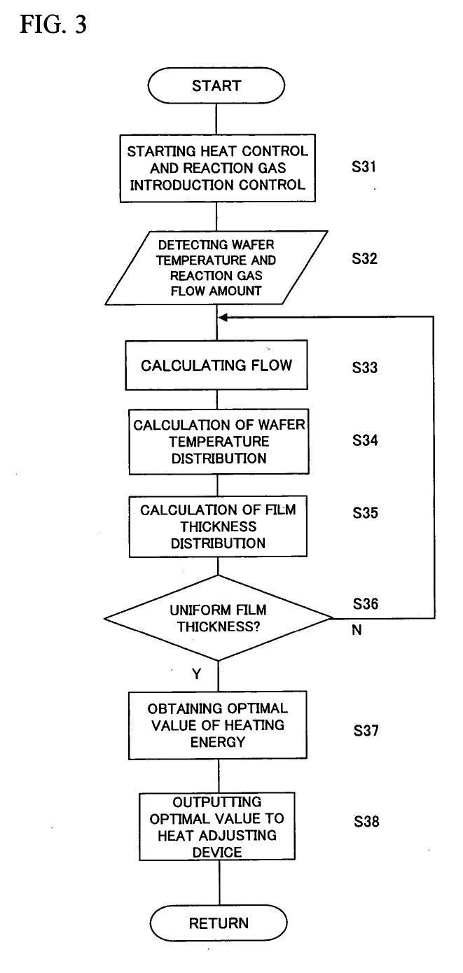

After setting the wafer W for an epitaxial film to grow to the susceptor of the chamber 11, as shown in FIG. 3, the heat adjusting device 16 supplies power of an initial value to the heaters 131 to 134, respectively (step S31). As a result, the wafer fed to the chamber 11 is heated to a predetermined temperature of, for example, 1100° C. When the wafer W reaches the predetermined temperature, the reaction gas is introduced from the gas inlet 111 by the gas introduction device 12 (step S31). As a result, an epitaxial film starts to grow on the wafer W surface.

When heat control and reaction gas introduction control start in the step S31, the control deice 17 retrieves a temperature T1 of the center and a temperature T2 around the wafer surface from the temperatures sensors 141 and 142 at certain time intervals (step S32). Also, the control device 17 retrieves from the gas flow amount sensor 15 a flow amount Q of the reaction gas sent from the gas introduction device 12 to the chamber 11 at certain time intervals (step S32).

When actual temperatures T1 and T2 of the wafer and an actual reaction gas flow amount Q are retrieved in the step S32, they are used as parameters for executing calculation of a flow by the simulation model shown in FIG. 2 (step S33). Namely, an actual temperature distribution as shown in the center of FIG. 2 is calculated (step S34), and a film thickness distribution is calculated from the obtained reaction gas flow amount Q as shown in the lower part of FIG. 2 (step S35).

Next, in a step S36, whether the obtained film thickness distribution is in a range of satisfying desired film thickness uniformity or not is determined and, when not in the satisfying range, the procedure returns back to the step S33 to calculate power to be supplied to the heaters 131 to 134 and the distribution ratio (balance between the heaters) again by the simulation model. In the step S36, when the obtained film thickness distribution becomes the most uniform, power supplied to each of the heaters 131 to 134 at that time is considered as an optimal power value (step S37) and sent to the heat adjusting device 16 (step S38).

Then, the procedure again returns to the step S31, wherein the optimal power value output in the previous step S38 is output to the heaters 131 to 134 and the wafer W is heated by the power. The processing as above continues until growing of the epitaxial film completes.

In the present embodiment, the reaction gas flow amount Q and the wafer temperatures T1 and T2, which become main factors in growing a uniform epitaxial film, are actually measured and assigned to the simulation program of the control device 17, so that a desired optimal power value (heating energy) can be obtained in a short time and feedback control in real-time can be attained.

Furthermore, a computer simulation method of the related art was unable to predict deterioration of the heater over time and change of a flow amount of the reaction gas, so that an accurate expected value could not be obtained, while in the present embodiment, the reaction gas flow amount Q and wafer temperatures T1 and T2 are actually measured and assigned to the simulation program, so that it is possible to respond to deterioration of the heaters 131 to 134 over time if any, and an epitaxial film can be grown based on an accurate expected value.

### Second Embodiment

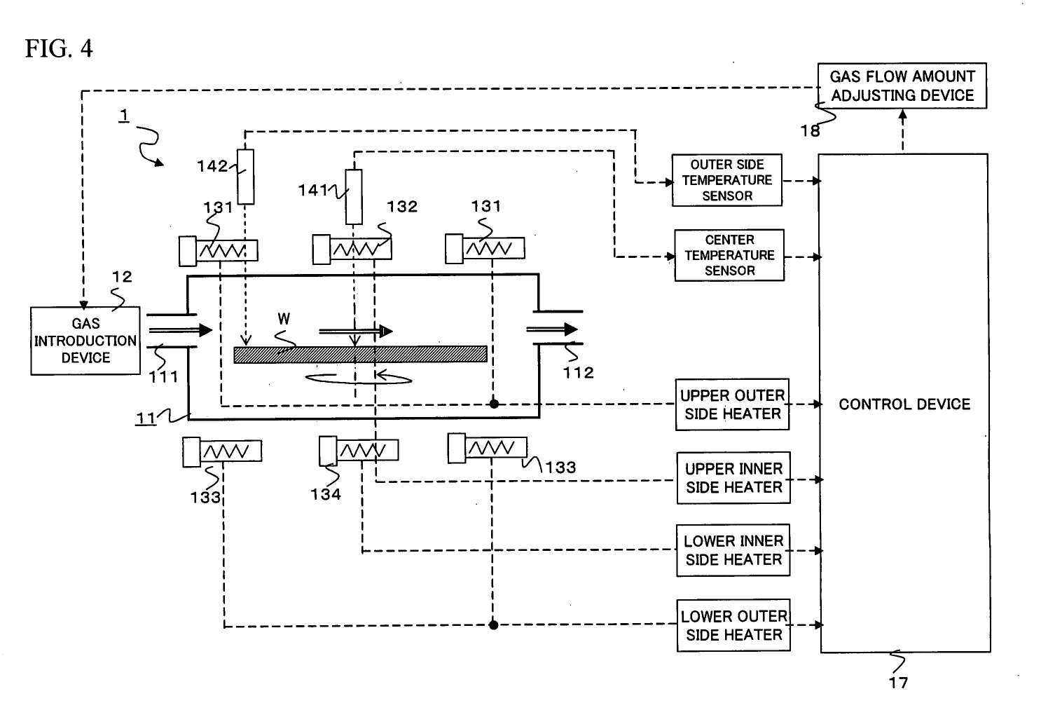

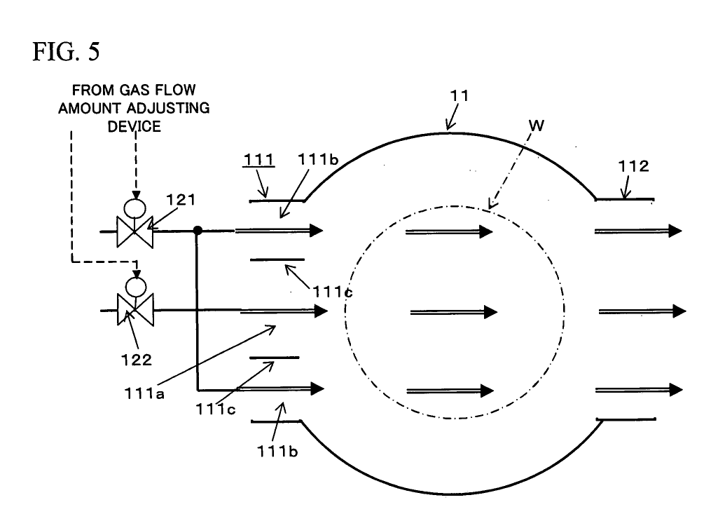

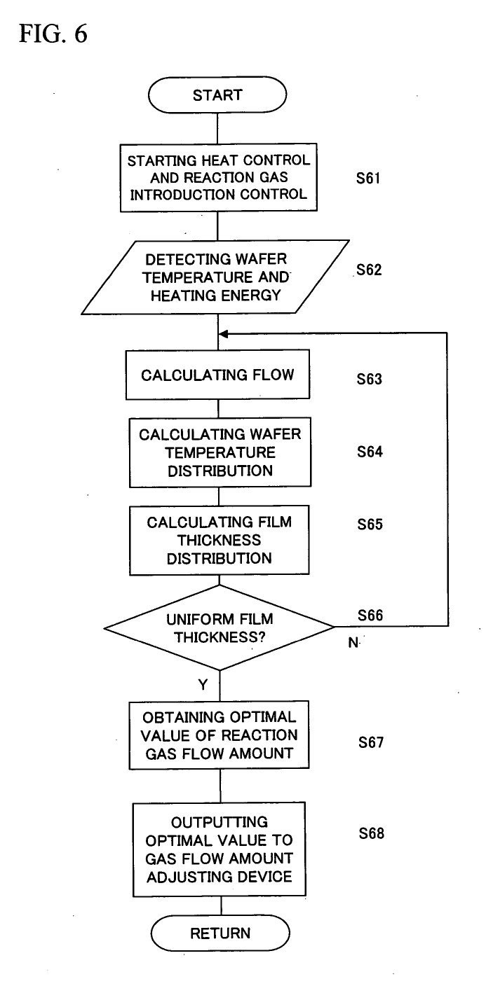

FIG. 4 is a block diagram of a vapor phase epitaxial growth apparatus according to a second embodiment of the present invention, FIG. 5 is a plan view of a chamber in FIG. 4, and FIG. 6 is a flowchart of a control procedure in a control device in FIG. 4.

The present embodiment is also the same single wafer vapor phase epitaxial growth apparatus 1 (hereinafter, also simply referred to as a vapor phase growth apparatus 1) as that in the first embodiment and, while the detailed configuration is omitted in the drawings, provided with a chamber 11 composed of an upper dome and a lower dome 4 attached to a dome mounting body. The upper dome and the lower dome composing the chamber 11 are made by quartz or other translucent material, and a plurality of heaters composed of a halogen lamp as a heating source are provided to upper and lower parts of the chamber 11 so as to heat a wafer W fed into the chamber 11.

The heaters include upper outer side heaters 131 arranged at the outer side of an upper portion of the chamber 11, an upper inner side heater 132 similarly arranged at the inner side of the upper portion, lower outer side heaters 133 arranged at the outer side of a lower portion of the chamber 11 and a lower inner side heater 134 similarly arranged at the inner side of the lower portion, and they are collectively called as heaters 13. The respective heaters 131 to 134 are configured, so that their abilities (power supplied to the heaters) to heat the wafer W can be adjusted by a not shown heat adjusting device.

A side surface of the chamber 11 is provided with a gas inlet 111, and a facing side surface thereto of the chamber 11 is provided with a gas outlet 112. A reaction gas obtained by diluting a Si source, such as SiHCl₃, with a hydrogen gas and mixing therein a trace of dopant is introduced into the chamber 11 from the gas inlet 111 via the gas introduction device 12 and the introduced reaction gas passes through a surface of the wafer W to grow an epitaxial film, then, discharged from the gas outlet 112 to the outside of the vapor phase growth apparatus 1. A double-lined arrow in FIG. 4 and FIG. 5 indicates the reaction gas flow.

Particularly, in the present embodiment, the gas inlet 111 is divided to a center gas inlet 111a for introducing the reaction gas to the center of the wafer W and an outer side gas inlet 111b for supplying the reaction gas to the outer side of the wafer W by a bulkhead 111c. A flow amount of the reaction gas introduced to the center gas inlet 111a is adjusted by a flow amount adjusting valve 122 and a flow amount of the reaction gas introduced to the outer side gas inlet 11b is adjusted by the flow amount adjusting valve 121. Opening degrees of the flow amount adjusting valves 121 and 122 are adjusted by an instruction from the gas flow amount adjusting device 18.

The gas introduction device 12 comprises a pump for pneumatically transferring the reaction gas and carrier gas, a gas pipe for guiding the gas and flow amount adjusting valves for adjusting a flow amount of the gas. The gas pipe and the flow amount adjusting valves 121 and 122 are shown in FIG. 5.

Note that the gas inlet 111 and the gas outlet 112 may be respectively divided into two gas inlets and two gas outlets, each of the upper and lower portions, so that the reaction gas can be introduced and discharged by using an upper gas inlet and an upper gas outlet while a carrier gas, such as a hydrogen gas, can be introduced to a lower side of the wafer W and discharged by using a lower gas inlet and a lower gas outlet. Consequently, dopant released from a back surface of the wafer W can be more effectively discharged to the outside of the vapor phase growth apparatus 1. Alternately, when introducing a carrier gas, such as a hydrogen gas, into the chamber 11 by dividing the gas inlet 111 to an upper part and a lower part, the reaction gas and the carrier gas for discharging the back surface dopant may be discharged from one gas-outlet 112. Note that the specific configuration of the gas inlet 111 and the gas outlet 112 does not matter in the present invention and may be modified in accordance with need. For instance, when the gas inlet 111 is divided to upper and lower parts, the carrier gas for discharging the back surface dopant is irrelevant to growth of the epitaxial film, so that it is not necessary to divide to the center gas inlet 111a and the outer side gas inlet 111b as in the gas inlet for introducing the reaction gas.

While not illustrated in FIG. 1, the wafer W fed into the chamber 11 is loaded on a support plate called a susceptor. The susceptor rotates at a predetermined speed by being driven by a rotation axis rotating about a center point of the wafer W (refer to an arrow). A material of the susceptor is not particularly limited and, for example, what obtained by coating a SiC film on a surface of a carbon base material is preferably used. Note that a method of conveying the wafer W to and from the susceptor is not particularly limited, and either of a type of conveying the wafer by elevating and lowering a conveyor jig by using a Verneuil chuck and a type of supporting the lower surface of the wafer by a pin and conveying by elevating and lowering the pin may be applied.

Particularly, the vapor phase growth apparatus 1 of the present embodiment is provided with a center temperature sensor 141 composed of a radiation thermometer for detecting a temperature at the center (near the center) of the wafer W surface and an outer side temperature sensor 142 composed of a radiation thermometer for detecting a temperature around the wafer W. As explained above, since the wafer W rotates at a constant speed due to rotation of the susceptor, the outer side temperature sensor 142 measures a temperature at certain time intervals to evenly obtain temperatures around the wafer W. Then, actual temperatures of the wafer surface detected by the center temperature sensor 141 and the outer side temperature sensor 142 are sent to the control device 17.

The control device 17 controls sends an instruction to the gas flow amount adjusting device 18 to control the opening degrees of the two flow amount adjusting valves 121 and 122 and receives power values P1 to P4 at certain time intervals from a control device (not shown) of the heaters 131 to 134. Also, the control device 17 retrieves an actual temperature T1 of the center of the wafer W surface from the center temperature sensor 141 at certain time intervals and an actual temperature T2 around the wafer W surface from the outer side temperature sensor 142 at certain time intervals.

Then, the control device 17 calculates an actual temperature distribution as shown in FIG. 2 from the obtained surface-temperatures T1 and T2 of the wafer and power values of the heaters 131 to 134 and calculates a film thickness distribution. Here, when the obtained film thickness distribution is not in a range of satisfying desired film thickness uniformity, opening degrees of the flow amount adjusting valves 121 and 122 and a ratio of the opening degrees (balance between the flow amount adjusting valves) are calculated based on the simulation model, and optimal values of the opening degrees of the flow amount adjusting valves 121 and 122 when the film thickness becomes the most uniformity is obtained among that. Then, the obtained optimal opening degrees are sent to the gas flow amount adjusting device 18, and the gas flow amount adjusting device 18 sends an instruction of the obtained optimal opening degrees to the two flow amount adjusting valves 121 and 122.

Next, an operation of the vapor phase growth apparatus of the present embodiment will be explained.

After setting the wafer W for an epitaxial film to grow to the susceptor of the chamber 11, as shown in FIG. 6, the heat adjusting device 16 supplies power of an initial value to the heaters 131 to 134, respectively (step S61). As a result, the wafer fed to the chamber 11 is heated to a predetermined temperature of, for example, 1100° C. When the wafer W reaches the predetermined temperature, the flow amount adjusting valves 121 and 122 are opened to be the initial opening degrees and the reaction gas is introduced to the chamber 11 from the gas inlet 111 by the gas introduction device 12 (step S31). As a result, an epitaxial film starts to grow on the wafer W surface.

When heat control and reaction gas introduction control start in the step S61, the control deice 17 retrieves a center temperature T1 and a peripheral temperature T2 of the wafer surface from the temperatures sensors 141 and 142 at certain time intervals (step S62). Also, the control device 17 retrieves power values P (heating energy) to be supplied to the heaters 131 to 134 from a control device of the heaters 131 to 134 at certain time intervals (step S62).

When actual temperatures T1 and T2 of the wafer and actual power values P of the heaters are retrieved in the step S62, they are used as parameters for executing calculation of a flow by the simulation model shown in FIG. 2 (step S63). Namely, an actual temperature distribution as shown in the center of FIG. 2 is calculated (step S64), and a film thickness distribution is calculated as shown in the lower part of FIG. 2 (step S65).

Next, in a step S66, whether the obtained film thickness distribution is in a range of satisfying desired film thickness uniformity or not is determined and when not in the satisfying range, the procedure returns back to the step S63 to calculate opening degrees of the flow amount adjusting valves 121 and 122 and the distribution ratio again by the simulation model. In the step S66, when the obtained film thickness distribution becomes the most uniform, opening degrees of the flow amount adjusting valves 121 and 122 at that time are considered as optimal opening degrees (step S67) and sent to the gas flow amount adjusting device 18 (step S68).

Then, the procedure returns again to the step S61, wherein the optimal opening degrees output in the previous step S68 are output to the flow amount adjusting valves 121 and 122, and the reaction gas is supplied to the wafer W by the opening degrees. The processing as above continues until growing of the epitaxial film completes.

In the present embodiment, the heating energy P by the heaters and the wafer temperatures T1 and T2, which become main factors in growing a uniform epitaxial film, are actually measured and assigned to the simulation program of the control device 17, so that desired optimal opening degrees (reaction gas flow amounts) can be obtained in a short time and feedback control in real-time can be attained.

Furthermore, a computer simulation method of the related art was unable to predict deterioration of the heater over time and change of a flow amount of the reaction gas, so that an accurate expected value could not be obtained, while in the present embodiment, the power values P of the heaters 131 to 134 and wafer temperatures T1 and T2 are actually measured and assigned to the simulation program, so that it is possible to respond to deterioration of the heaters 131 to 134 over time if any, and an epitaxial film can be grown based on an accurate expected value.

Note that the embodiments explained above are for easier understanding of the present invention and not to limit the present invention. Accordingly, respective elements disclosed in the above embodiments include all modifications in designs and equivalents belonging to the technical field of the present invention.

For example, in the second embodiment explained above, the reaction gas introduced into the chamber 11 was divided to flow to the center and the outer side of the wafer W by dividing the gas inlet 111 for the reaction gas to the center gas inlet 111a and the outer side gas inlet 111b by two bulkheads 111c; but the reaction gas can be divided to flow to the center and the outer side of the wafer W by providing a movable louver instead of the fixed bulkheads 111c and changing an angle of the movable louver. In that case, an instruction signal from the gas flow amount adjusting device 18 is sent to a drive portion of the movable louver.

1. A vapor phase epitaxial growth apparatus, comprising:
a chamber, to which a wafer is fed;
a gas introduction device for introducing a reaction gas to the chamber;
a gas flow amount detector for detecting a flow amount of the reaction gas introduced by the gas introduction device;
a heater for heating the wafer fed into the chamber;
a heat adjusting device for adjusting heating energy by the heater;
a temperature detector for detecting a temperature of the wafer fed into the chamber;
a controller for receiving as parameters a gas flow amount detected by the gas flow amount detector and a wafer temperature detected by the temperature detector, obtaining an optimal value of heating energy for attaining the most uniform epitaxial film based on a predetermined simulation model, and outputting the same to the heat adjusting device.

2. A vapor phase epitaxial growth apparatus, comprising:
a chamber, to which a wafer is fed;
a gas introduction device for introducing a reaction gas to the chamber;
a gas flow amount adjusting device for adjusting a flow amount of the reaction gas by the gas introduction device;
a heater for heating the wafer fed into the chamber;
a heating energy detector for detecting heating energy supplied by the heater;
a temperature detector for detecting a temperature of the wafer fed into the chamber;
a controller for receiving as parameters heating energy detected by the heating energy detector and a wafer temperature detected by the temperature detector, obtaining an optimal value of a reaction gas flow amount for attaining the most uniform epitaxial film based on a predetermined simulation model, and outputting the same to the gas flow amount adjusting device.

3. The vapor phase epitaxial growth apparatus as set forth in claim 1, wherein:
the heater comprises an upper inner side heater provided at an inner side of an upper portion of the chamber, an upper outer side heater provided at an outer side of the upper portion, a lower inner side heater provided at an inner side of a lower portion of the chamber and a lower outer side heater provided at an outer side of the lower portion;
the controller obtains optimal values of heating energy of the respective heater and outputting the same to the heat adjusting device; and
the heat adjusting device adjusts the heating energy of the respective heater.

4. The vapor phase epitaxial growth apparatus as set forth in claim 2, wherein:
the gas introduction device comprises a center gas introduction device for introducing a reaction gas to the center of the wafer fed into the chamber and an outer side gas introduction device for introducing the reaction gas to the outer side of the wafer fed into the chamber;
the controller obtains optimal values of reaction gas flow amounts of the respective gas introduction device and outputting the same to the gas flow amount adjusting device; and
the gas flow amount adjusting device adjusts flow amounts of the reaction gas of the respective gas introduction device.

5. The vapor phase epitaxial growth apparatus as set forth in claim 1 any one of claims 1 to 4, wherein the temperature detector comprises a center temperature detector for detecting a temperature of the center of the wafer fed into the chamber and a periphery temperature detector for detecting a temperature around the wafer.

6. A production method of a semiconductor wafer for heating a wafer fed into a chamber and introducing a reaction gas into the chamber to form an epitaxial film on a surface of said wafer by thermal decomposition of the reaction gas, comprising the steps of:
detecting a flow amount of the reaction gas introduced into the chamber;
detecting a temperature of the wafer fed into the chamber;
inputting as parameters the gas flow amount detected by the above step and the wafer temperature detected by the above step, and obtaining an optimal value of heating energy for attaining the most uniform epitaxial film based on a predetermined simulation model; and
heating the wafer by the optimal value of heating energy obtained in the above step.

7. A production method of a semiconductor wafer for heating a wafer fed into a chamber and introducing a reaction gas into the chamber to form an epitaxial film on a surface of the wafer by thermal decomposition of said reaction gas, comprising the steps of:
detecting heating energy supplied to the wafer fed into the chamber;
detecting a temperature of the wafer fed into the chamber;
inputting as parameters the heating energy detected in the above step and the wafer temperature detected in the above step, and obtaining an optimal value of a reaction gas flow amount for attaining the most uniform epitaxial film based on a predetermined simulation model; and
introducing the reaction gas into the chamber by the optimal value of the reaction gas flow amount obtained in the above step.

8. The production method of a semiconductor wafer as set forth in claim 6, comprising the steps of:
heating the wafer fed into the chamber by a plurality of heater;
obtaining optimal values of heating energy of the respective heater; and
heating the wafer by the optimal values of the respective heater obtained in the above step.

9. The production method of a semiconductor wafer as set forth in claim 7, comprising the steps of:
introducing a reaction gas into the chamber by a gas introduction device for introducing the reaction gas to the center of the wafer and a gas introduction device for introducing the reaction gas to the outer side of the wafer;
obtaining optimal values of the reaction gas flow amounts of the respective gas introduction device; and
introducing the reaction gas into the chamber by the optimal values of the respective gas introduction device obtained in the above step.

10. The production method of a semiconductor wafer as set forth in claim 6, wherein a temperature of the center of the wafer and a temperature around the wafer are detected in the step of detecting the temperature of the wafer fed into the chamber.

11. The vapor phase epitaxial growth apparatus as set forth in claim 2, wherein the temperature detector comprises a center temperature detector for detecting a temperature of the center of the wafer fed into the chamber and a periphery temperature detector for detecting a temperature around the wafer.

12. The vapor phase epitaxial growth apparatus as set forth in claim 3, wherein the temperature detector comprises a center temperature detector for detecting a temperature of the center of the wafer fed into the chamber and a periphery temperature detector for detecting a temperature around the wafer.

13. The vapor phase epitaxial growth apparatus as set forth in claim 4, wherein the temperature detector comprises a center temperature detector for detecting a temperature of the center of the wafer fed into the chamber and a periphery temperature detector for detecting a temperature around the wafer.

14. The production method of a semiconductor wafer as set forth in claim 7, wherein a temperature of the center of the wafer and a temperature around the wafer are detected in the step of detecting the temperature of the wafer fed into the chamber.

15. The production method of a semiconductor wafer as set forth in claim 8, wherein a temperature of the center of the wafer and a temperature around the wafer are detected in the step of detecting the temperature of the wafer fed into the chamber.

16. The production method of a semiconductor wafer as set forth in claim 9, wherein a temperature of the center of the wafer and a temperature around the wafer are detected in the step of detecting the temperature of the wafer fed into the chamber.
